(19) United States
(12) Patent Application Publication
(10) Pub. No.: US 2025/0126976 A1
(43) Pub. Date: Apr. 17, 2025

(54) DISPLAY DEVICE

(71) Applicant: Samsung Display Co., LTD., Yongin-si (KR)

(72) Inventors: Hwi KIM, Yongin-si (KR); Jung Sun PARK, Yongin-si (KR); Ji Hee SON, Yongin-si (KR); Seoul Ki LEE, Yongin-si (KR); Seung Jun LEE, Yongin-si (KR); A Reum LEE, Yongin-si (KR); Yeon Hwa LEE, Yongin-si (KR); Joon Gu LEE, Yongin-si (KR)

(21) Appl. No.: 18/646,268

(22) Filed: Apr. 25, 2024

(30) Foreign Application Priority Data
Oct. 16, 2023 (KR) 10-2023-0137794

(51) Int. Cl. H10K 59/122; H10K 59/35; H10K 102/00

(52) U.S. Cl. CPC H10K 59/122; H10K 59/353; H10K 2102/351

(57) ABSTRACT

A display device includes: a first pixel electrode on a substrate; a pixel defining layer on the substrate and exposing the first pixel electrode; a first light emitting layer on the first pixel electrode; a first common electrode on the first light emitting layer; a first bank on the pixel defining layer; a second bank on the first bank and including side surfaces protruding more than side surfaces of the first bank; and a third bank on upper and lower surfaces of the second bank and including a hydrophobic material.

### CROSS-REFERENCE TO RELATED APPLICATION

The present application claims priority to and the benefit of Korean Patent Application No. 10-2023-0137794, filed on Oct. 16, 2023, in the Korean Intellectual Property Office, the entire content of which is incorporated herein by reference.

### BACKGROUND

### 1. Field

One or more embodiments of the present disclosure relates to a display device and a method of fabricating the display device.

### 2. Description of the Related Art

As the information society develops, demands for display devices for displaying images are increasing in one or more suitable forms. For example, display devices are applied to one or more suitable electronic devices such as smartphones, digital cameras, notebook computers, navigation devices, and smart televisions. The display devices may be flat panel display devices, such as liquid crystal display devices, field emission display devices, and/or organic light emitting display devices. Among these flat panel display devices, a light emitting display device includes a light emitting element that enables each pixel of a display panel to emit light by itself. Thus, the light emitting display device may display an image without a backlight unit that would provide light to the display panel.

Recently, display devices have been applied to glasses-like devices for providing virtual reality and augmented reality. To be applied to a glasses-like device, a display device is implemented in a relatively small size of 2 inches or less. However, the display device should have a relatively high pixel density in order to have a relatively high resolution. For example, the display device may have a high pixel density of 400 pixels per inch (PPI) or more.

When a display device is implemented in a relatively small size but has a relatively high pixel density as described above, it is difficult to implement a separate light emitting element in each emission area through a mask process because the area of the emission area in which the light emitting element is disposed and provided is reduced.

### SUMMARY

One or more aspects of embodiments of the present disclosure are directed toward a display device in which a separate light emitting element may be formed in each emission area without a mask process.

One or more aspects of embodiments of the present disclosure are directed toward a display device in which a difference in light emission between pixels is reduced.

However, aspects of the disclosure are not restricted to the one set forth herein. The above and other aspects of the disclosure will become more apparent to one of ordinary skill in the art to which the disclosure pertains by referencing the detailed description of the disclosure provided herein.

According to one or more embodiments of the present disclosure, a display device includes: a first pixel electrode on (e.g., disposed on) a substrate; a pixel defining layer on (e.g., disposed on) the substrate and exposing the first pixel electrode; a first light emitting layer on (e.g., disposed on) the first pixel electrode; a first common electrode on (e.g., disposed on) the first light emitting layer; a first bank on (e.g., disposed on) the pixel defining layer; a second bank on (e.g., disposed on) the first bank and including side surfaces protruding more than side surfaces of the first bank; and a third bank on (e.g., disposed on) upper and lower surfaces of the second bank.

A thickness of the third bank may be about 5 nanometers (nm) to about 100 nm.

A thickness of the third bank on (e.g., disposed on) the upper surface of the second bank and a thickness of the third bank on (e.g., disposed on) the lower surface of the second bank may be different from each other.

In one or more embodiments, the display device may further include a first inorganic layer on (e.g., disposed on) the third bank and the first common electrode.

The third bank may completely cover the second bank.

The third bank may contact at least a portion of the lower surface of the second bank.

The third bank may include a hydrophobic material.

The third bank may be a self-assembled monolayer.

The third bank may include fluorine (F).

The third bank may include an —O— or —S— bond (e.g., an —O-metal bond or an —S-metal bond) on a surface of the second bank.

The second bank may include a second lower bank on (e.g., disposed on) the first bank and a second upper bank on (e.g., disposed on) the second lower bank, the second upper bank may include gold (Au), and the third bank may include an —S— bond on a surface of the second upper bank.

In one or more embodiments, the display device may further include a first capping layer between the first common electrode and the first inorganic layer.

An end and the other end of the first common electrode may contact the first bank.

In one or more embodiments, the display device may further include: a second pixel electrode on (e.g., disposed on) the substrate and spaced and/or apart from the first pixel electrode; a second light emitting layer on (e.g., disposed on) the second pixel electrode; a second common electrode on (e.g., disposed on) the second light emitting layer and spaced and/or apart from the first common electrode; and a second inorganic layer on (e.g., disposed on) the second common electrode and the second bank and spaced and/or apart from the first inorganic layer.

In one or more embodiments, the display device may further include: a first light emitting pattern between the third bank and the first inorganic layer and including the same material as the first light emitting layer; and a first electrode pattern between the first light emitting pattern and the first inorganic layer and including the same material as the first common electrode.

According to one or more embodiments of the present disclosure, a display device may include: a first pixel electrode on (e.g., disposed on) a substrate; a pixel defining layer on (e.g., disposed on) the substrate and exposing the first pixel electrode; a first light emitting layer on (e.g., disposed on) the first pixel electrode; a first common electrode on (e.g., disposed on) the first light emitting layer; a first bank on (e.g., disposed on) the pixel defining layer; a second bank on (e.g., disposed on) the first bank and including side surfaces protruding more than side surfaces of the first bank; and a third bank on (e.g., disposed on) the second bank and including fluorine (F).

The third bank may be on (e.g., disposed on) upper and side surfaces of the second bank.

The third bank may include a hydrophobic material.

In one or more embodiments, the third bank may include an —O— or —S— bond (e.g., an —O-metal bond or an —S-metal bond) on a surface of the second bank.

In one or more embodiments, the third bank may form an —O—P— or —O—Si— bond with a surface of the second bank.

According to the display device of one or more embodiments, a third bank on (e.g., disposed on) the second bank may be included to prevent or reduce an etchant from penetrating into the light emitting element in an etching process. Damage to the light emitting element due to etching solution and/or moisture is prevented or reduced, and thus a difference in luminance between the light emitting elements may be reduced.

However, the effects and benefits of the present disclosure are not limited to the aforementioned effects and benefits, and one or more suitable other effects and benefits are included in the present disclosure.

### BRIEF DESCRIPTION OF THE DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. These and/or other aspects will become apparent and more readily appreciated from the following description of the embodiments, taken in conjunction with the accompanying drawings in which:

FIG. 1 is a perspective view of a display device according to one or more embodiments of the present disclosure;

FIG. 2 is a cross-sectional view of the display device of FIG. 1 as viewed from a side of the display device;

FIG. 3 is a plan view illustrating an arrangement of light emitting elements, a lower inorganic encapsulation layer, and a third bank in the display device according to one or more embodiments of the present disclosure;

FIG. 4 is a cross-sectional view of a portion of the display device according to one or more embodiments of the present disclosure;

FIG. 5 is an enlarged view of area A1 of FIG. 4 according to one or more embodiments of the present disclosure;

FIG. 6 is an enlarged view of a display device according to one or more embodiments of the present disclosure;

FIG. 7 is an enlarged view of a display device according to one or more embodiments of the present disclosure;

FIG. 8 is an enlarged view of a display device according to one or more embodiments of the present disclosure;

FIG. 9 is a cross-sectional view illustrating penetration of an etchant into a light emitting element in a display device not including a third bank according to one or more embodiments of the present disclosure;

FIG. 10 is a cross-sectional view illustrating prevention of moisture penetration in a display device including a third bank according to one or more embodiments of the present disclosure; and

FIG. 11 is a schematic cross-sectional view of a self-assembled monolayer in area A2 of FIG. 5 according to one or more embodiments of the present disclosure.

### DETAILED DESCRIPTION

Advantages and features of the disclosure and methods of accomplishing the same may be understood more readily by reference to the following detailed description of embodiments and the accompanying drawings. The disclosure may, however, be embodied in many different forms and should not be construed as being limited to the embodiments set forth herein. Rather, these embodiments are provided so that this disclosure will be thorough and complete and will fully convey the concept of the disclosure to those skilled in the art, and the disclosure will only be defined by the appended claims.

It will be understood that when an element or layer is referred to as being “on” another element or layer, the element or layer may be directly on another element or layer or on intervening elements or layers. In contrast, “directly on” may refer to that there are no additional intervening elements or layers between the element or layer and the another element or layer. Likewise, when an element or layer is referred to as being “below” or on a “left” or “right” side of another element or layer, the element or layer may be directly adjacent to another element or layer or adjacent to intervening layers or materials. Like reference numerals refer to like elements throughout the present disclosure, and duplicative descriptions thereof may not be provided for conciseness.

It will be understood that, although the terms first, second, third, etc., may be utilized herein to describe one or more suitable elements, these elements should not be limited by these terms. These terms are only utilized to distinguish one element from another element. Thus, a first element discussed could be termed a second element without departing from the teachings of the present disclosure.

Hereinafter, embodiments of the present disclosure will be described in more detail with reference to the accompanying drawings.

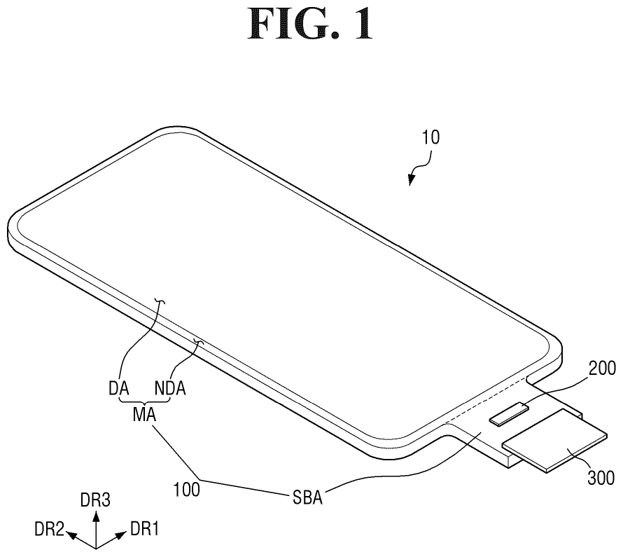

FIG. 1 is a perspective view of a display device 10 according to one or more embodiments of the present disclosure.

Referring to FIG. 1, the display device 10 according to one or more embodiments may be included in an electronic device to provide a screen displayed by the electronic device. The electronic device may refer to any electronic device that provides a display screen. Non-limiting examples of the electronic device may include televisions, notebook computers, monitors, billboards, Internet of things (IoT) devices, mobile phones, smartphones, tablet personal computers (PCs), electronic watches, smart glasses, smart watches, watch phones, head mounted displays, mobile communication terminals, electronic notebooks, electronic books, portable multimedia players (PMPs), navigation devices, game machines, digital cameras and camcorders, all of which provide one or more display screens.

The shape of the display device 10 may be variously modified. For example, in one or more embodiments, the display device 10 may have a shape similar to a rectangle having short sides in a first direction DR1 and long sides in a second direction DR2. Each corner where a short side extending in the first direction DR1 meets a long side extending in the second direction DR2 may be rounded with a curvature. However, embodiments of the present disclosure are not limited thereto, in some embodiments, each corner may be right-angled. The planar shape of the display device 10 is not limited to a quadrangular shape but may also be similar to other polygonal shapes, a circular shape, or an oval shape.

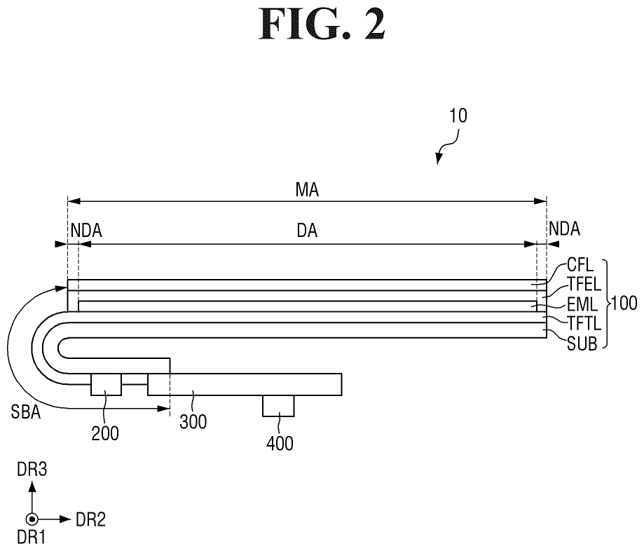

In one or more embodiments, the display device 10 may include a display panel 100, a display driver 200, a circuit board 300, and a touch driver 400 (referring to FIG. 2).

The display panel 100 may include a main area MA and a sub-area SBA.

The main area MA may include a display area DA including pixels that display an image and a non-display area NDA disposed around (e.g., surrounding) the display area DA. The display area DA may be to emit light from a plurality of emission areas or a plurality of opening areas. For example, in one or more embodiments, the display panel 100 may include pixel circuits including switching elements, a pixel defining layer defining the emission areas or the opening areas, and self-light emitting elements.

For example, in one or more embodiments, each of the self-light emitting elements may include, but is not limited to, at least one of an organic light emitting diode including an organic light emitting layer, a quantum dot light emitting diode including a quantum dot light emitting layer, an inorganic light emitting diode including an inorganic semiconductor, or a micro-light emitting diode.

A plurality of pixels, a plurality of scan lines, a plurality of data lines, and a plurality of power lines may be disposed and provided in the display area DA. Each of the pixels may be defined as a minimum unit that emits light, and the above-described self-light emitting elements may be the pixels, respectively. The scan lines may supply scan signals received from a scan driver to the pixels. The data lines may supply data voltages received from the display driver 200 to the pixels. The power lines may supply a power supply voltage received from the display driver 200 to the pixels.

The non-display area NDA may be an area outside (e.g., surrounding or being around) the display area DA. The non-display area NDA may be defined as an edge area of the main area MA of the display panel 100. The non-display area NDA may include the scan driver which supplies scan signals to the scan lines and fan-out lines which connect the display driver 200 and the display area DA.

The sub-area SBA may extend from a side of the main area MA. The sub-area SBA may include a flexible material that may be bent, folded, rolled, etc. For example, when the sub-area SBA is bent, it may be overlapped by the main area MA in a thickness direction (third direction DR3). The sub-area SBA may include the display driver 200 and a pad unit connected to the circuit board 300. In some embodiments, the sub-area SBA may not be provided, and the display driver 200 and the pad unit may be disposed and provided in the non-display area NDA.

The display driver 200 may output signals and voltages for driving the display panel 100. The display driver 200 may supply data voltages to the data lines. The display driver 200 may supply a power supply voltage to the power lines and supply a scan control signal to the scan driver. The display driver 200 may be formed as an integrated circuit and mounted on the display panel 100 by a chip on glass (COG) method, a chip on plastic (COP) method, or an ultrasonic bonding method. For example, in some embodiments, the display driver 200 may be disposed and provided in the sub-area SBA and may be overlapped by the main area MA in the thickness direction (third direction DR3) by the bending of the sub-area SBA. In some embodiments, the display driver 200 may be mounted on the circuit board 300.

The circuit board 300 may be attached onto the pad unit of the display panel 100 utilizing an anisotropic conductive film (ACF). Lead lines of the circuit board 300 may be electrically connected to the pad unit of the display panel 100. The circuit board 300 may be a flexible printed circuit board, a printed circuit board, or a flexible film such as a chip on film.

FIG. 2 is a cross-sectional view of the display device 10 of FIG. 1 as viewed from a side of the display device according to one or more embodiments. For example, FIG. 2 illustrates a side of the display device 10 of FIG. 1 in a folded state.

Referring to FIG. 2, the display panel 100 may include a substrate SUB, a thin-film transistor layer TFTL, a light emitting element layer EML, a thin-film encapsulation layer TFEL, and a color filter layer CFL.

The substrate SUB may be a base substrate or a base member. The substrate SUB may be a flexible substrate that may be bent, folded, rolled, etc. For example, in some embodiments, the substrate SUB may include polymer resin such as polyimide (PI), but embodiments of the present disclosure are not limited thereto. In one or more embodiments, the substrate SUB may include a glass material or a metal material.

The thin-film transistor layer TFTL may be on (e.g., disposed on) the substrate SUB. The thin-film transistor layer TFTL may include a plurality of thin-film transistors constituting pixel circuits of pixels. The thin-film transistor layer TFTL may further include scan lines, data lines, power lines, scan control lines, fan-out lines connecting the display driver 200 and the data lines, and lead lines connecting the display driver 200 and the pad unit. Each of the thin-film transistors may include a semiconductor region, a source electrode, a drain electrode, and a gate electrode. For example, in some embodiments, when the scan driver is formed on a side of the non-display area NDA of the display panel 100, it may include thin-film transistors.

The thin-film transistor layer TFTL may be in (e.g., disposed in) the display area DA, the non-display area NDA, and the sub-area SBA. The thin-film transistors of the pixels, the scan lines, the data lines, and the power lines of the thin-film transistor layer TFTL may be in (e.g., disposed in) the display area DA. The scan control lines and the fan-out lines of the thin-film transistor layer TFTL may be in (e.g., disposed in) the non-display area NDA. The lead lines of the thin-film transistor layer TFTL may be in (e.g., disposed in) the sub-area SBA.

The light emitting element layer EML may be on (e.g., disposed on) the thin-film transistor layer TFTL. The light emitting element layer EML may include a plurality of light emitting elements, each including a first electrode, a second electrode, a light emitting layer to emit light, and a pixel defining layer defining the pixels. The light emitting elements of the light emitting element layer EML may be in (e.g., disposed in) the display area DA.

In one or more embodiments, the light emitting layer may be an organic light emitting layer including an organic material. The light emitting layer may include a hole transporting layer, an organic light emitting layer, and an electron transporting layer. When the first electrode receives a voltage through a thin-film transistor of the thin-film transistor layer TFTL and the second electrode receives a cathode voltage, holes and electrons may move to the organic light emitting layer through the hole transporting layer and the electron transporting layer, respectively. Then, the holes and the electrons may be combined with each other in the organic light emitting layer to emit light.

In one or more embodiments, each of the light emitting elements may include a quantum dot light emitting diode including a quantum dot light emitting layer, an inorganic light emitting diode including an inorganic semiconductor, or a micro-light emitting diode.

The thin-film encapsulation layer TFEL may cover upper and side surfaces of the light emitting element layer EML and may protect the light emitting element layer EML. The thin-film encapsulation layer TFEL may include at least one inorganic layer and at least one organic layer to encapsulate the light emitting element layer EML.

The color filter layer CFL may be on (e.g., disposed on) the thin-film encapsulation layer TFEL. The color filter layer CFL may include a plurality of color filters corresponding to a plurality of emission areas, respectively. Each of the color filters may selectively transmit light of a specific wavelength and block or reduce or absorb light of other wavelengths. The color filter layer CFL may be to absorb a part of light coming from the outside of the display device 10, thereby reducing reflected light caused by the external light. Therefore, the color filter layer CFL may prevent or reduce color distortion caused by reflection of external light.

Because the color filter layer CFL is directly on (e.g., disposed on) the thin-film encapsulation layer TFEL, the display device 10 may not require a separate substrate for the color filter layer CFL. Therefore, a thickness of the display device 10 may be relatively small.

In some embodiments, the display device 10 may further include an optical device. The optical device may be to emit or receive light in an infrared, ultraviolet, or visible light band. For example, in one or more embodiments, the optical device may be an optical sensor that senses light incident on the display device 10, such as a proximity sensor, an illuminance sensor, a camera sensor, a fingerprint sensor, or an image sensor.

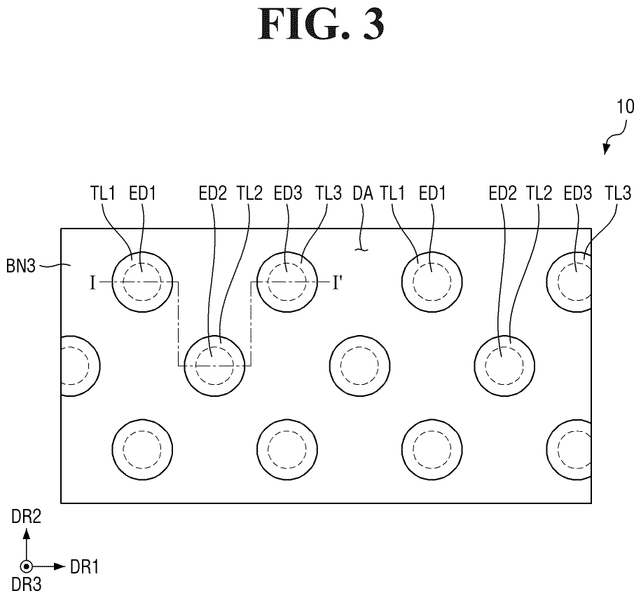

FIG. 3 is a plan view of a portion of the display device 10 according to one or more embodiments. FIG. 3 is a plan view illustrating the arrangement of light emitting elements ED1 through ED3, a lower inorganic encapsulation layer TL1 through TL3, and a third bank BN3 in the display area DA of the display device 10.

Referring to FIG. 3, the third bank BN3 may cover the display area DA but partially expose the display area DA. Openings (dotted areas in FIG. 3) may be formed in areas exposed without being covered by the third bank BN3, and the light emitting elements ED1 through ED3 may be disposed and provided in the openings, respectively. The lower inorganic encapsulation layer TL1 through TL3 may be disposed and provided on the third bank BN3 to cover boundary portions of the openings and may cover the light emitting elements ED1 through ED3 within the openings.

In FIG. 3, the areas exposed without being covered by the third bank BN3 are circular. However, the areas may also have a polygonal shape such as a triangle, a quadrangle, or a hexagon. In some embodiments, the shape of the lower inorganic encapsulation layer TL1 through TL3 which covers the exposed areas and portions around the exposed areas may also be changed accordingly. A portion of the lower inorganic encapsulation layer TL1 through TL3 may be disposed and provided at a higher level than the third bank BN3, and the light emitting elements ED1 through ED3 may be disposed and provided at a lower level than the third bank BN3.

In one or more embodiments, the light emitting elements ED1 through ED3 may be arranged in a PenTile™ type or kind, for example, a diamond PenTile™ type or kind. PenTile™ is a trademark of Samsung Display Co., Ltd. For example, in one or more embodiments, first light emitting elements ED1 and third light emitting elements ED3 may be spaced and/or apart from each other in the first direction DR1 and may be alternately disposed in the first direction DR1 and the second direction DR2. Each second light emitting element ED2 may be spaced and/or apart from other adjacent second light emitting elements ED2 in the first direction DR1 and the second direction DR2. The second light emitting elements ED2 and the first light emitting elements ED1 or the second light emitting elements ED2 and the third light emitting elements ED3 may be alternately disposed along any one direction in a plane formed by the first direction DR1 and the second direction DR2 (e.g., in a plan view). The shapes and arrangement of the areas exposed without being covered by the third bank BN3 and the light emitting elements ED1 through ED3 are not limited to those in FIG. 3.

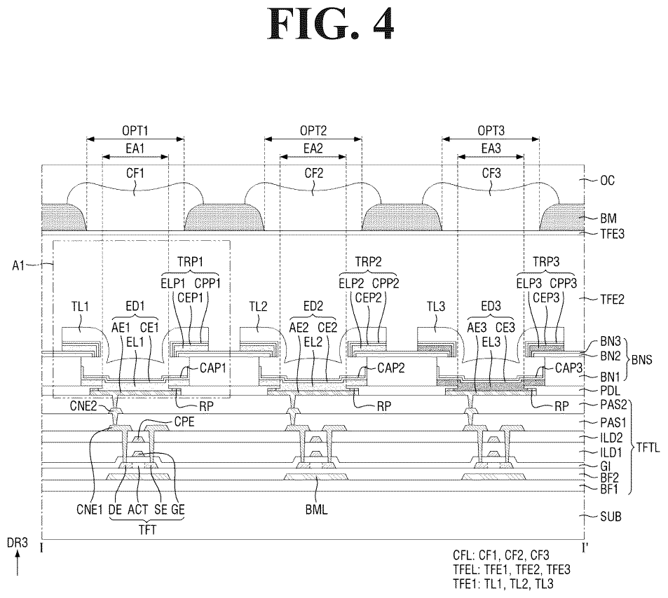

FIG. 4 is a cross-sectional view of a portion of the display device 10 according to one or more embodiments. For example, FIG. 4 is a cross-sectional view of portion I-I′ of FIG. 3. FIG. 4 illustrates cross sections of the substrate SUB, the thin-film transistor layer TFTL, the light emitting element layer EML, the thin-film encapsulation layer TFEL, and the color filter layer CFL.

The thin-film transistor layer TFTL may include a first buffer layer BF1, bottom metal layers BML, a second buffer layer BF2, thin-film transistors TFT, a gate insulating layer GI, a first interlayer insulating layer ILD1, capacitor electrodes CPE, a second interlayer insulating layer ILD2, first connection electrodes CNE1, a first passivation layer PAS1, second connection electrodes CNE2, and a second passivation layer PAS2.

The first buffer layer BF1 may be on (e.g., disposed on) the substrate SUB. The first buffer layer BF1 may include an inorganic layer that can prevent or reduce penetration of air and/or moisture. For example, in some embodiments, the first buffer layer BF1 may include a plurality of inorganic layers stacked alternately.

The bottom metal layers BML may be on (e.g., disposed on) the first buffer layer BF1. For example, each of the bottom metal layers BML may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

The second buffer layer BF2 may cover the first buffer layer BF1 and the bottom metal layers BML. The second buffer layer BF2 may include an inorganic layer that can prevent or reduce penetration of air and/or moisture. For example, in some embodiments, the second buffer layer BF2 may include a plurality of inorganic layers stacked alternately.

The thin-film transistors TFT may be on (e.g., disposed on) the second buffer layer BF2. The thin-film transistors TFT may constitute respective pixel circuits of a plurality of pixels. For example, each of the thin-film transistors TFT may be a driving transistor or a switching transistor of a pixel circuit. Each of the thin-film transistors TFT may include a semiconductor layer ACT, a source electrode SE, a drain electrode DE, and a gate electrode GE.

The semiconductor layer ACT may be on (e.g., disposed on) the second buffer layer BF2. The semiconductor layer ACT may overlap a bottom metal layer BML and the gate electrode GE in the thickness direction DR3 and may be insulated from the gate electrode GE by the gate insulating layer GI. In portions of the semiconductor layer ACT, a material of the semiconductor layer ACT may be made conductive to form the source electrode SE and the drain electrode DE.

The gate electrode GE may be on (e.g., disposed on) the gate insulating layer GI. The gate electrode GE may overlap the semiconductor layer ACT in the thickness direction DR3 with the gate insulating layer GI interposed therebetween.

The gate insulating layer GI may be on (e.g., disposed on) the semiconductor layers ACT. For example, the gate insulating layer GI may cover the semiconductor layers ACT and the second buffer layer BF2 and may insulate the semiconductor layers ACT from the gate electrodes GE. The gate insulating layer GI may include contact holes through which the first connection electrodes CNE1 pass.

The first interlayer insulating layer ILD1 may cover the gate electrodes GE and the gate insulating layer GI. The first interlayer insulating layer ILD1 may include contact holes through which the first connection electrodes CNE1 pass. The contact holes of the first interlayer insulating layer ILD1 may be connected to the contact holes of the gate insulating layer GI and contact holes of the second interlayer insulating layer ILD2.

The capacitor electrodes CPE may be on (e.g., disposed on) the first interlayer insulating layer ILD1. The capacitor electrodes CPE may overlap the gate electrodes GE in the thickness direction DR3. The capacitor electrodes CPE and the gate electrodes GE may form capacitances.

The second interlayer insulating layer ILD2 may cover the capacitor electrodes CPE and the first interlayer insulating layer ILD1. The second interlayer insulating layer ILD2 may include the contact holes through which the first connection electrodes CNE1 pass. The contact holes of the second interlayer insulating layer ILD2 may be connected to the contact holes of the first interlayer insulating layer ILD1 and the contact holes of the gate insulating layer GI.

The first connection electrodes CNE1 may be on (e.g., disposed on) the second interlayer insulating layer ILD2. The first connection electrodes CNE1 may electrically connect the drain electrodes DE of the thin-film transistors TFT to the second connection electrodes CNE2. The first connection electrodes CNE1 may be inserted into the contact holes formed in the second interlayer insulating layer ILD2, the first interlayer insulating layer ILD1, and the gate insulating layer GI to contact the drain electrodes DE of the thin-film transistors TFT.

The first passivation layer PAS1 may cover the first connection electrodes CNE1 and the second interlayer insulating layer ILD2. The first passivation layer PAS1 may protect the thin-film transistors TFT. The first passivation layer PAS1 may include contact holes through which the second connection electrodes CNE2 pass.

The second connection electrodes CNE2 may be on (e.g., disposed on) the first passivation layer PAS1. The second connection electrodes CNE2 may electrically connect the first connection electrodes CNE1 to corresponding pixel electrodes AE1 through AE3 of light emitting elements ED. The second connection electrodes CNE2 may be inserted into the contact holes formed in the first passivation layer PAS1 to contact the first connection electrodes CNE1.

The second passivation layer PAS2 may cover the second connection electrodes CNE2 and the first passivation layer PAS1. The second passivation layer PAS2 may include contact holes through which the pixel electrodes AE1 through AE3 of the light emitting elements ED pass.

The light emitting element layer EML may be on (e.g., disposed on) the thin-film transistor layer TFTL. The light emitting element layer EML may include the light emitting elements ED, a pixel defining layer PDL, capping layers CAP (CAP1 through CAP3), and a bank structure BNS. The light emitting elements ED may include the pixel electrodes AE1 through AE3, light emitting layers EL1 through EL3, and common electrodes CE1 through CE3.

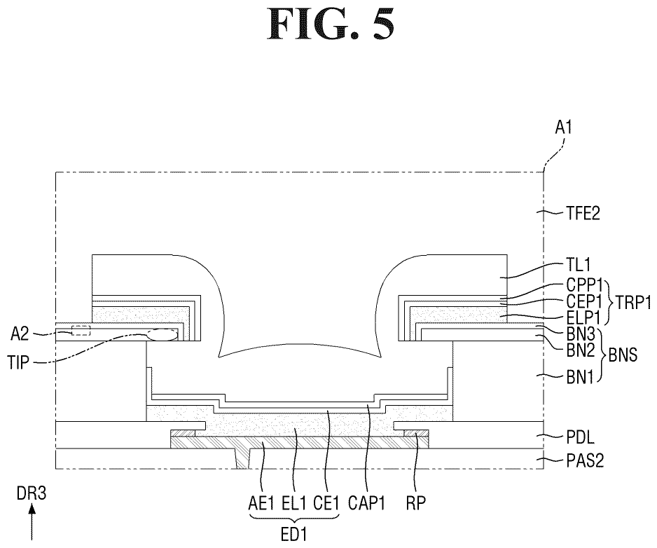

FIG. 5 is an enlarged view of a first emission area EA1 of FIG. 4 according to one or more embodiments of the present disclosure, specifically, area A1 of FIG. 4.

Referring to FIG. 5 in addition to FIG. 4, the display device 10 may include a plurality of emission areas EA1 through EA3 in (e.g., disposed in) the display area DA. The emission areas EA1 through EA3 may include areas where light is emitted from the light emitting elements ED1 through ED3 including the pixel electrodes AE1 through AE3, the light emitting layers EL1 through EL3 and the common electrodes CE1 through CE3 stacked sequentially and passes through the color filter layer CFL in the third direction DR3. The emission areas EA1 through EA3 may include the first emission area EA1, a second emission area EA2, and a third emission area EA3 spaced and/or apart from each other and emitting light of the same color or different colors.

In one or more embodiments, the first through third emission areas EA1 through EA3 may have the same area or size. For example, in some embodiments, in the display device 10, the first emission area EA1, the second emission area EA2, and the third emission area EA3 may have substantially the same area. However, embodiments of the present disclosure are not limited thereto. In the display device 10, the first through third emission areas EA1 through EA3 may also have different areas or sizes. For example, in some embodiments, an area of the second emission area EA2 may be larger than an area of the first emission area EA1 and an area of the third emission area EA3, and the area of the third emission area EA3 may be larger than the area of the first emission area EA1. The intensity of light emitted from each of the emission areas EA1 through EA3 may vary according to the area of the emission area EA1, EA2 or EA3, and the color of a screen displayed on the display device 10 may be controlled or selected by adjusting the area of each of the emission areas EA1 through EA3. In the embodiment of FIG. 4, the emission areas EA1 through EA3 have substantially the same area. However, embodiments of the present disclosure are not limited thereto.

In the display device 10, one first emission area EA1, one second emission area EA2, and one third emission area EA3 adjacent to each other may form one pixel group. One pixel group may include the emission areas EA1 through EA3 emitting light of different colors to express a white gray level. However, embodiments of the present disclosure are not limited thereto, and the combination of the emission areas EA1 through EA3 constituting one pixel group can be variously and suitably modified according to the arrangement of the emission areas EA1 through EA3 and the colors of light emitted from the emission areas EA1 through EA3.

A plurality of openings formed in the bank structure BNS of the light emitting element layer EML are defined along the boundary of the bank structure BNS. A first bank BN1, a second bank BN2, and the third bank BN3 of the bank structure BNS may surround the emission areas EA1 through EA3. Each of the openings may include one of the first through third emission areas EA1 through EA3.

In one or more embodiments, the display device 10 may include a plurality of light emitting elements ED1 through ED3 disposed/provided in different emission areas EA1 through EA3. The light emitting elements ED1 through ED3 may include a first light emitting element ED1 in (e.g., disposed in) the first emission area EA1, a second light emitting element ED2 in (e.g., disposed in) the second emission area EA2, and a third light emitting element ED3 in (e.g., disposed in) the third emission area EA3.

The light emitting elements ED1 through ED3 may include the pixel electrodes AE1 through AE3, the light emitting layers EL1 through EL3, and the common electrodes CE1 through CE3, respectively. The light emitting elements ED1 through ED3 disposed/provided in different emission areas EA1 through EA3 may be to emit light of different colors depending on materials of the light emitting layers EL1 through EL3. For example, in one or more embodiments, the first light emitting element ED1 in (e.g., disposed in) the first emission area EA1 may be to emit red first light having a peak wavelength of 610 nanometer (nm) to 650 nm, the second light emitting element ED2 in (e.g., disposed in) the second emission area EA2 may be to emit green second light having a peak wavelength of 510 nm to 550 nm, and the third light emitting element ED3 in (e.g., disposed in) the third emission area EA3 may be to emit blue third light having a peak wavelength of 440 nm to 480 nm. The first through third emission areas EA1 through EA3 constituting one pixel group may include the light emitting elements ED1 through ED3 emitting light of different colors to express a white gray level. In some embodiments, the light emitting layers EL1 through EL3 may include two or more materials emitting light of different colors, so that one light emitting layer may emit mixed light. For example, in some embodiments, the light emitting layers EL1 through EL3 may include a red light emitting material and a green light emitting material to emit yellow light or may include a red light emitting material, a green light emitting material, and a blue light emitting material to emit white light (e.g., combined white light).

The pixel electrodes AE1 through AE3 may be on (e.g., disposed on) the second passivation layer PAS2. The pixel electrodes AE1 through AE3 may be in (e.g., disposed in) the emission areas EA1 through EA3, respectively. The pixel electrodes AE1 through AE3 may include a first pixel electrode AE1 in (e.g., disposed in) the first emission area EA1, a second pixel electrode AE2 in (e.g., disposed in) the second emission area EA2, and a third pixel electrode AE3 in (e.g., disposed in) the third emission area EA3. The first pixel electrode AE1, the second pixel electrode AE2, and the third pixel electrode AE3 may be spaced and/or apart from each other on the second passivation layer PAS2.

The pixel electrodes AE1 through AE3 may be electrically connected to the corresponding drain electrodes DE of the thin-film transistors TFT through the first and second connection electrodes CNE1 and CNE2. The first through third pixel electrodes AE1 through AE3 may be insulated from each other by the pixel defining layer PDL covering edges of the pixel electrodes AE1 through AE3 spaced and/or apart from each other.

The pixel electrodes AE1 through AE3 may include a transparent electrode material or/and a conductive metal material. The metal material may be at least one of silver (Ag), copper (Cu), aluminum (Al), nickel (Ni), lanthanum (La), titanium (Ti), or titanium nitride (TiN). The transparent electrode material may be at least one of indium tin oxide (ITO), indium zinc oxide (IZO), or indium tin zinc oxide (ITZO). In some embodiments, the pixel electrodes AE1 through AE3 may have a multilayer structure of the transparent electrode material and the conductive metal material.

The pixel defining layer PDL may be on (e.g., disposed on) the second passivation layer PAS2, residual patterns RP, and the pixel electrodes AE1 through AE3. The pixel defining layer PDL may be disposed on the entire surface of the second passivation layer PAS2 but may (e.g., may just) cover side surfaces of the pixel electrodes AE1 through AE3 and the residual patterns RP to partially expose upper surfaces of the pixel electrodes AE1 through AE3. For example, the pixel defining layer PDL may expose the first pixel electrode AE1 in the first emission area EA1, and a first light emitting layer EL1 may be directly on (e.g., disposed on) the first pixel electrode AE1.

The pixel defining layer PDL may include an inorganic insulating material. The pixel defining layer PDL may include, but is not limited to, at least one of a silicon nitride layer, a silicon oxynitride layer, a silicon oxide layer, a titanium oxide layer, an aluminum oxide layer, a tantalum oxide layer, a hafnium oxide layer, a zinc oxide layer, or an amorphous silicon layer.

According to one or more embodiments, the pixel defining layer PDL may be on (e.g., disposed on) the pixel electrodes AE1 through AE3, but may be spaced and/or apart from the upper surfaces of the pixel electrodes AE1 through AE3. The pixel defining layer PDL may partially overlap the upper surfaces of the pixel electrodes AE1 through AE3 in the thickness direction DR3 of the substrate SUB but may not directly contact the upper surfaces of the pixel electrodes AE1 through AE3, and the residual patterns RP may be disposed and provided between the pixel defining layer PDL and the pixel electrodes AE1 through AE3. However, the pixel defining layer PDL may directly contact the side surfaces of the pixel electrodes AE1 through AE3. Side surfaces of the pixel defining layer PDL may protrude toward the emission areas EA1 through EA3 more than side surfaces of the second bank BN2.

The residual patterns RP may be on (e.g., disposed on) the edges of each of the pixel electrodes AE1 through AE3. The pixel defining layer PDL may not directly contact the upper surfaces of the pixel electrodes AE1 through AE3 due to the residual patterns RP. The residual patterns RP may be formed when sacrificial layers disposed on the pixel electrodes AE1 through AE3 are partially removed during a process of fabricating the display device 10. The residual patterns RP may include a metal or an oxide semiconductor material. In the drawings (e.g., FIG. 4 through FIG. 10), side surfaces of the residual patterns RP which face the emission areas EA1 through EA3 are recessed more than the side surfaces of the pixel defining layer PDL. However, embodiments of the present disclosure are not limited thereto. The side surfaces of the residual patterns RP may also be aligned with the side surfaces of the pixel defining layer PDL or may protrude more than the side surfaces of the pixel defining layer PDL toward the emission areas EA1 through EA3. The side surfaces of the pixel defining layer PDL may be outermost side surfaces facing the emission areas EA1 through EA3.

The light emitting layers EL1 through EL3 may be on (e.g., disposed on) the pixel electrodes AE1 through AE3. In one or more embodiments, the light emitting layers EL1 through EL3 may be organic light emitting layers made of organic materials and may be formed on the pixel electrodes AE1 through AE3 through a deposition process. Each of the light emitting layers EL1 through EL3 may have a multilayer structure, and a hole injecting material, a hole transporting material, a light emitting material, an electron transporting material, and/or an electron injecting material may form respective layers. When the thin-film transistors TFT apply a set or predetermined voltage to the corresponding pixel electrodes AE1 through AE3 of the light emitting elements ED1 through ED3 and the common electrodes CE1 through CE3 of the light emitting elements ED1 through ED3 receive a common voltage or a cathode voltage, holes and electrons may be injected and transported and then may be combined with each other in the light emitting layers EL1 through EL3 to emit light.

The light emitting layers EL1 through EL3 may include the first light emitting layer EL1, a second light emitting layer EL2, and a third light emitting layer EL3 disposed and provided in different emission areas EA1 through EA3, respectively. The first light emitting layer EL1 may be on (e.g., disposed on) the first pixel electrode AE1 in the first emission area EA1, the second light emitting layer EL2 may be on (e.g., disposed on) the second pixel electrode AE2 in the second emission area EA2, and the third light emitting layer EL3 may be on (e.g., disposed on) the third pixel electrode AE3 in the third emission area EA3. The light emitting layers EL1 through EL3 may be to emit light of different colors, or one light emitting layer EL1, EL2 or EL3 may be to emit mixed light. In some embodiments, the first light emitting layer EL1 may be to emit red light, the second light emitting layer EL2 may be to emit green light, and the third light emitting layer EL3 may be to emit blue light. In some embodiments, the first light emitting layer EL1 may be to emit yellow light which is a mixture of red light and green light, and the second light emitting layer EL2 may be to emit blue light. In some embodiments, the first light emitting layer EL1 may be to emit white light which is a mixture of red light, green light, and blue light.

The light emitting layers EL1 through EL3 may be on (e.g., disposed on) an upper surface of the pixel defining layer PDL. In some embodiments, the light emitting layers EL1 through EL3 may be disposed in spaces between the pixel electrodes AE1 through AE3 and the pixel defining layer PDL. In some embodiments, the light emitting layers EL1 through EL3 may contact the pixel defining layer PDL, the residual patterns RP, and the corresponding pixel electrodes AE1 through AE3.

The common electrodes CE1 through CE3 may be on (e.g., disposed on) the corresponding light emitting layers EL1 through EL3. The common electrodes CE1 through CE3 may include a transparent conductive material to allow light generated by the light emitting layers EL1 through EL3 to pass therethrough. The common electrodes CE1 through CE3 may receive a common voltage or a low potential voltage. When the pixel electrodes AE1 through AE3 receive voltages corresponding to data voltages and the common electrodes CE1 through CE3 receive a low potential voltage, a potential difference may be formed between the pixel electrodes AE1 through AE3 and the common electrode CE1 through CE3. Accordingly, the light emitting layers EL1 through ED3 may be to emit light.

The common electrodes CE1 through CE3 may include a first common electrode CE1, a second common electrode CE2, and a third common electrode CE3 disposed and provided in different emission areas EA1 through EA3, respectively. The first common electrode CE1 may be on (e.g., disposed on) the first light emitting layer EL1 in the first emission area EA1, the second common electrode CE2 may be on (e.g., disposed on) the second light emitting layer EL2 in the second emission area EA2, and the third common electrode CE3 may be on (e.g., disposed on) the third light emitting layer EL3 in the third emission area EA3. The first through third common electrodes CE1 through CE3 may be spaced and/or apart from each other.

The capping layers CAP1 through CAP3 may be on (e.g., disposed on) the common electrodes CE1 through CE3, respectively. The capping layers CAP1 through CAP3 may include an organic or inorganic insulating material to cover the light emitting elements ED1 through ED3. The capping layers CAP1 through CAP3 may prevent or reduce the light emitting elements ED1 through ED3 from being damaged by external air. In one or more embodiments, the capping layers CAP1 through CAP3 may include an organic material such as N,N′-bis(naphthalen-1-yl)-N,N′-bis(phenyl)-2,2′-dimethylbenzidine (α-NPD), N,N′-bis(naphthalen-1-yl)-N,N′-bis(phenyl)-benzidine (NPB), N,N′-bis(3-methylphenyl)-N,N′-bis(phenyl)-benzidine (TPD), 4,4′,4″-tris(N-3-methylphenyl-N-phenyl-amino)-triphenylamine (m-MTDATA), tris(8-hydroxyquinolinato)aluminum (Alq₃), lithium fluoride (LiF), and/or copper (II) phthalocyanine (CuPc) or may include an inorganic material such as aluminum oxide, titanium oxide, tantalum oxide, hafnium oxide, zinc oxide, silicon oxide, silicon nitride, and/or silicon oxynitride.

The capping layers CAP1 through CAP3 may include a first capping layer CAP1, a second capping layer CAP2, and a third capping layer CAP3 disposed and provided in different emission areas EA1 through EA3, respectively. The first through third capping layers CAP1 through CAP3 may be spaced and/or apart from each other.

The display device 10 may include the bank structure BNS on (e.g., disposed on) the pixel defining layer PDL. The bank structure BNS may have a structure in which the banks BN1 through BN3 including different materials are sequentially stacked. The bank structure BNS may include a plurality of openings including the emission areas EA1 through EA3 and may overlap a light blocking layer BM which will be described later. The light emitting elements ED1 through ED3 of the display device 10 may overlap the openings of the bank structure BNS.

The bank structure BNS may include the first bank BN1, the second bank BN2, and the third bank BN3 sequentially stacked on the pixel defining layer PDL.

The first bank BN1 may be on (e.g., disposed on) the pixel defining layer PDL. Side surfaces of the first bank BN1 may be recessed more than the side surfaces of the pixel defining layer PDL in a direction opposite to (a direction facing directly away from) a direction toward the emission areas EA1 through EA3. The side surfaces of the first bank BN1 may be recessed more than the side surfaces of the second bank BN2, which will be described later, in the direction opposite to the direction toward the emission areas EA1 through EA3.

According to one or more embodiments, the first bank BN1 may include a metal material. In one or more embodiments, the first bank BN1 may include aluminum (Al) or an aluminum (Al) alloy.

In one or more embodiments, a thickness of the first bank BN1 may range from 4000 ångström (Å) to 7000 Å. When the above range is satisfied, the light emitting layers EL1 through EL3 and the common electrodes CE1 through CE3 separated from each other may be formed through deposition and etching processes rather than a mask process.

According to one or more embodiments, the common electrodes CE1 through CE3 may directly contact the side surfaces of the first bank BN1. An end and the other end of each of the common electrodes CE1 through CE may contact the side surfaces of the first bank BN1. The common electrodes CE1 through CE3 of different light emitting elements ED1 through ED3 may directly contact the first bank BN1, and the first bank BN1 may include a metal material. Therefore, the common electrodes CE1 through CE3 may be electrically connected to each other through the first bank BN1.

The light emitting layers EL1 through EL3 may directly contact the side surfaces of the first bank BN1. An area of contact between the common electrodes CE1 through CE3 and the side surfaces of the first bank BN1 may be larger than an area of contact between the light emitting layers EL1 through EL3 and the side surfaces of the first bank BN1. The common electrodes CE1 through CE3 may be disposed on a larger area of the side surfaces of the first bank BN1 or may be disposed to a higher position on the side surfaces of the first bank BN1 than the light emitting layers EL1 through EL3. Because the common electrodes CE1 through CE3 of different light emitting elements ED1 through ED3 are electrically connected through the first bank BN1, it may be advantageous for the common electrodes CE1 through CE3 to contact a larger area of the first bank BN1.

The second bank BN2 may be on (e.g., disposed on) the first bank BN1. The second bank BN2 may include tips TIP that protrude compared with the first bank BN1. The side surfaces of the second bank BN2 may protrude more than the side surfaces of the first bank BN1 toward the emission areas EA1 through EA3.

Because the side surfaces of the second bank BN2 protrude more than the side surfaces of the first bank BN1 toward the emission areas EA1 through EA3, an undercut structure of the first bank BN1 may be formed under each tip TIP of the second bank BN2.

In the display device 10 according to one or more embodiments, because the bank structure BNS includes the tips TIP protruding toward the emission areas EA1 through EA3, the light emitting layers EL1 through EL3 and the common electrodes CE1 through CE3 spaced and/or apart from each other may be formed through deposition and etching processes rather than a mask process. In some embodiments, different layers may be individually formed in different emission areas EA1 through EA3 even through a deposition process. For example, even when the light emitting layers EL1 through EL3 and the common electrodes CE1 through CE3 of the light emitting elements ED1 through ED3 are formed by a deposition process that does not utilize a mask, deposited materials may not be connected between the emission areas EA1 through EA3 but may be separated by the tips TIP of the second bank BN2 with the bank structure BNS interposed therebetween. After a material for forming a specific layer is formed on the entire surface of the display device 10, the layer formed in unwanted areas may be removed by etching. Through this process, different layers may be individually formed in different emission areas EA1 through EA3. In the display device 10, it may form different light emitting elements ED1 through ED3 in the emission areas EA1 through EA3 through deposition and etching processes without utilizing a mask process, may omit unnecessary components from the display device 10, and may minimize or reduce the area of the non-display area NDA.

The side shape of the bank structure BNS may be a structure (e.g., a shape) formed in an etching process due to a difference in etch rate between the first bank BN1 and the second bank BN2 including different materials. According to one or more embodiments, the second bank BN2 may include a material having a slower etch rate than that of the first bank BN1, and the first bank BN1 may be further etched during the etching process to expose lower surfaces of the tips TIP of the second bank BN2 and form an undercut under each tip TIP of the second layer BN2.

The second bank BN2 may include a metal material different from that of the first bank BN1. The metal material of the second bank BN2 may be a material that is removed together with the metal material of the first bank BN1 by dry etching but is not etched or is etched at a much slower etch rate than that of the first bank BN1 by wet etching. In one or more embodiments, the first bank BN1 may include aluminum (Al) or an aluminum (Al) alloy, and the second bank BN2 may include titanium (Ti) or a titanium (Ti) alloy.

The tips TIP of the second bank BN2 may overlap the common electrodes CE1 through CE3, the light emitting layers EL1 through EL3, and/or the pixel defining layer PDL in a direction DR3 perpendicular to the substrate SUB. An end and the other end of each of the common electrodes CE1 through CE3 may overlap the second bank BN2 in the thickness direction DR3 of the substrate SUB. A maximum vertical distance from the substrate SUB to each of the common electrodes CE1 through CE3 may be smaller than a maximum vertical distance from the substrate SUB to the second bank BN2.

The third bank BN3 may be on (e.g., disposed on) the second bank BN2. The third bank BN3 may completely cover an upper surface of the second bank BN2 and may cover the side surfaces of the second bank BN2. In some embodiments, the third bank BN3 may also be on (e.g., disposed on) a lower surface of the second bank BN2.

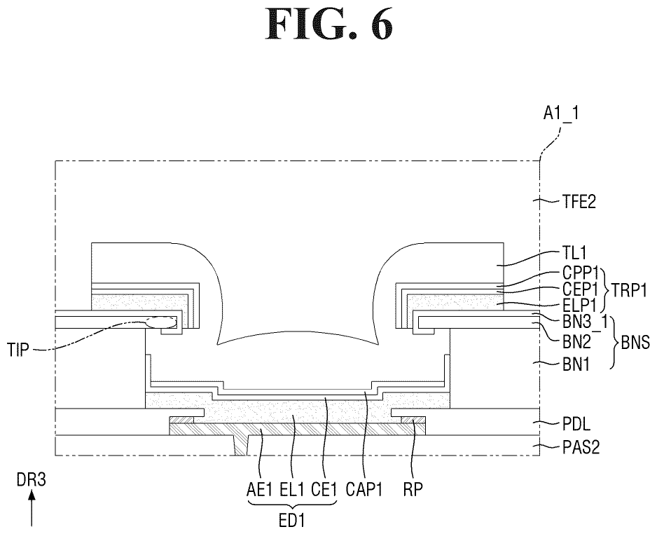

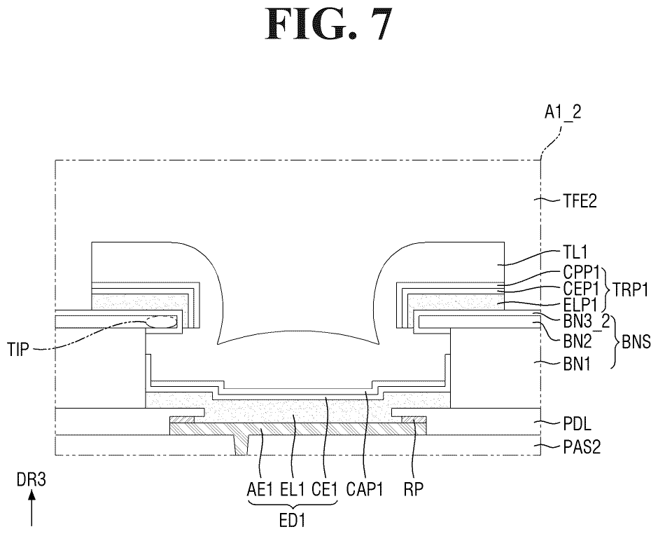

FIG. 6 is an enlarged view of a first emission area EA1 of a display device according to one or more embodiments of the present disclosure. FIG. 7 is an enlarged view of a first emission area EA1 of a display device according to one or more embodiments of the present disclosure.

FIG. 6 and FIG. 7 are different from FIG. 5 in that a third bank BN3_1 or BN3_2 is also on (e.g., disposed on) a lower surface of a second bank BN2. The third bank BN3_1 or BN3_2 may also be formed on lower surfaces of tips TIP of the second bank BN2. The third bank BN3_1 or BN3_2 may contact at least a portion of the lower surface of the second bank BN2.

In one or more embodiments, as illustrated in FIG. 6, the third bank BN3_1 may be disposed and provided on a portion of the lower surface of the second bank BN2 and may not be disposed and provided on the other portion. On the lower surface of each tip TIP of the second bank BN2, the third bank BN3_1 may be disposed and provided in an area adjacent to an emission area EA1, EA2, or EA3 and may not be disposed and provided in an area adjacent to a side surface of a first bank BN1. In one or more embodiments, as illustrated in FIG. 7, the third bank BN3_2 may completely cover the lower surfaces of the tips TIP of the second bank BN2.

The third bank BN3 may be formed through a wet coating or vacuum thermal evaporation process performed on the second bank BN2 after an undercut structure of the first bank BN1 is formed. The formation position and area of the third bank BN3 may be adjusted in the coating or evaporation process.

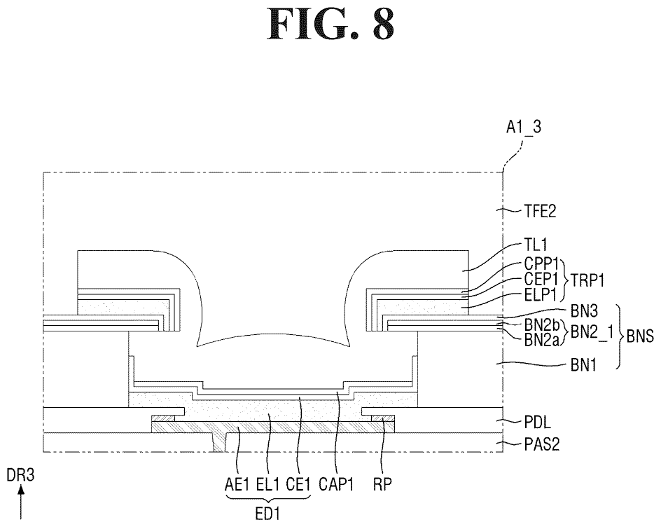

FIG. 8 is an enlarged view of a first emission area EA1 of a display device according to one or more embodiments. FIG. 8 is different from FIG. 5 in that a second bank BN2_1 has a multilayer structure. The second bank BN2_1 may include a second lower bank BN2a on (e.g., disposed on) a first bank BN1 and a second upper bank BN2b on (e.g., disposed on) the second lower bank BN2a. The second upper bank BN2b may include a different material from the second lower bank BN2a and may include a material with excellent or suitable adhesion to a third bank BN3, thereby increasing the durability of a display panel. In one or more embodiments, the second lower bank BN2a may include titanium (Ti), and the second upper bank BN2b may include gold (Au).

In one or more embodiments, a thickness of the third bank BN3 may be about 5 nm to about 100 nm. In this range, the third bank BN3 may be formed smoothly and may have an excellent or suitable moisture permeability effect. The third bank BN3 may be disposed on the upper surface, the side surfaces, and/or the lower surface of the second bank BN2. Here, the thickness of the third bank BN3 may be maintained constant or may vary according to positions. In some embodiments, the thickness of the third bank BN3 on (e.g., disposed on) the upper surface of the second bank BN2 and the thickness of the third bank BN3 on (e.g., disposed on) the lower surface of the second bank BN2 may be different from each other. In a coating or deposition process for forming the third bank BN3, the thickness of the third bank BN3 may be adjusted according to positions.

In some embodiments, after a first light emitting layer EL1/a first light emitting pattern ELP1, a first common electrode CE1/a first electrode pattern CEP1, a first capping layer CAP1/a first capping pattern CPP1, and a first inorganic layer TL1 are sequentially stacked, a mask is formed to cover the first emission area EA1 and a portion around the first emission area EA1. Then, the first inorganic layer TL1, the first capping layer CAP1, the first common electrode CE1, and the first light emitting layer EL1 in an area not covered by the mask are sequentially removed. The removal of the first light emitting pattern ELP1 may be performed by wet etching.

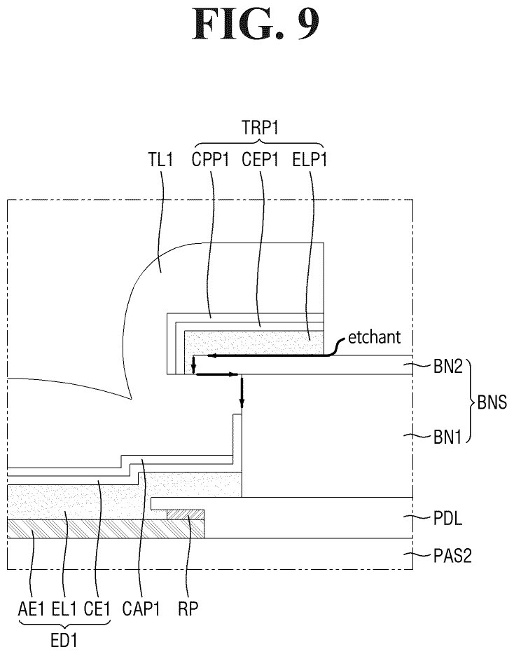

Here, when the third bank BN3 is not disposed on the second bank BN2 as illustrated in FIG. 9, when the first light emitting pattern ELP1 is removed, an etchant may penetrate between the second bank BN2 and the first light emitting patterns ELP1 to reach the light emitting element ED1 under the tips TIP of the second bank BN2. The penetration of the etchant may deteriorate and damage the first light emitting element ED1 and, by extension, cause a dark spot on the display panel.

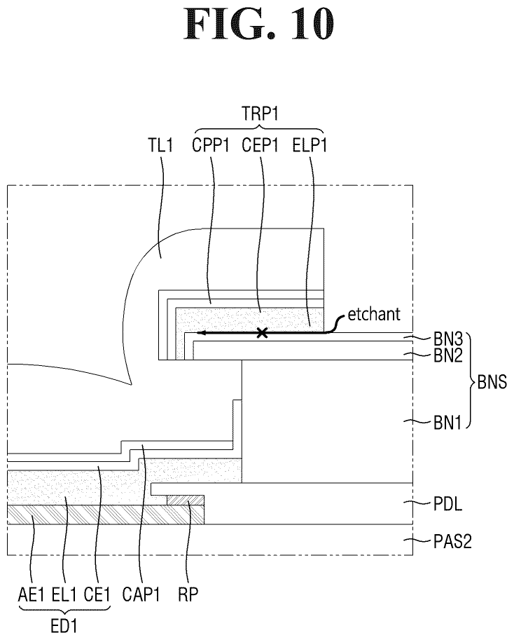

In contrast, when the third bank BN3 is disposed and provided on the second bank BN2 as illustrated in FIG. 10, the third bank BN3 may prevent or reduce penetration of an etchant at an interface with the first light emitting pattern ELP1. Because the etchant does not reach the first light emitting element ED1, damage to the light emitting element ED1 may be prevented or reduced, and a difference in luminance between light emitting elements may be reduced.

The third bank BN3 may be hydrophobic by including a hydrophobic material (e.g., by including or having a hydrophobic moiety). The hydrophobic material included in the third bank BN3 may prevent or reduce the etchant from penetrating the interface between the first light emitting pattern ELP1 and the third bank BN3.

The third bank BN3 may be a self-assembled monolayer. In one or more embodiments, the third bank BN3 may be a perfluorinated self-assembled monolayer and may include fluorine (F).

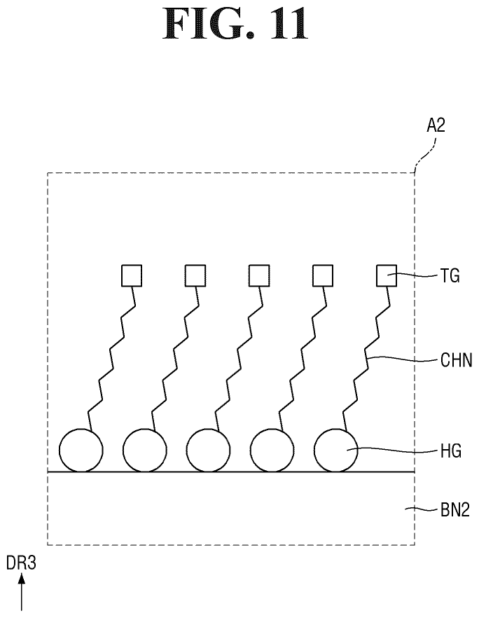

FIG. 11 schematically illustrates a cross section of area A2 of FIG. 5 according to one or more embodiments of the present disclosure, that is, an interface between the second bank BN2 and the third bank BN3. The self-assembled monolayer of the third bank BN3 is an organic assembly formed by adsorption of molecular components from a solution or gas phase. The self-assembled monolayer may include a self-assembled single molecule including a head group HG attached to the surface of the second bank BN2, a terminal group TG at an end, and a chain CHN connecting the head group HG and the terminal group TG. A plurality of self-assembled single molecules, each including the head group HG, the chain CHN, and the terminal group TG, may be aligned to form a layer. The self-assembled single molecules of FIG. 11 may be applied not only to the display device of FIG. 5 but also to the display devices of FIGS. 6 through 8.

The head group HG of the third bank BN3 may be a portion attached to the second bank BN2 under the third bank BN3 and may include an —O— or —S— bond (e.g., an —O-metal bond or an —S-metal bond). In other words, the third bank BN3 may be connected to the second bank BN2 through the —O— or —S— bond (e.g., an —O-metal bond or an —S-metal bond). In one or more embodiments, the head group HG of the third bank BN3 may form an —O—P— or —O—Si— bond with the surface of the second bank BN2. For example, the head group HG may include one of the following structures. In the structures, a wavy line is a position connected to the second bank BN2, a dotted line is a position connected to the chain CHN, and Ar is an aromatic hydrocarbon ring or an aromatic heterocycle and may be substituted with a substituent.

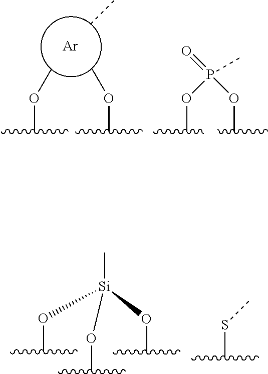

The chain CHN of the third bank BN3 may include a carbon-carbon skeleton and may include a carbonyl or amine bond. The number of carbons in the chain CHN may be 2 to 20. One or more of hydrogens included in the chain CHN may be replaced with fluorine (F).

The terminal group TG of the third bank BN3 may determine the surface properties of the third bank BN3. When the terminal group TG is a hydrophobic group such as fluorine (F), the surface of the third bank BN3 may be hydrophobic.

In one or more embodiments, a single molecule including the head group HG, the chain CHN, and the terminal group TG may have a molecular weight of 500 to 2000. In one or more embodiments, the single molecule may include a skeleton of an aromatic hydrocarbon ring or an aromatic heterocycle.

In one or more embodiments, the single molecule may include at least one of alkanethiols (e.g., alkyl thiols), alkylsiloxanes, or alkanephosphonic acids (e.g., alkyl phosphonic acids). In one or more embodiments, the single molecule may include (e.g., be) one of the following structures. In the structures, hydrogen may be replaced with fluorine (F).

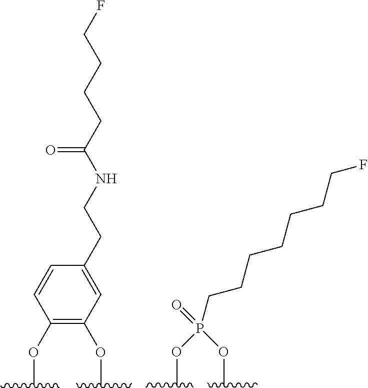 [SMILES: *Oc1ccc(CCNC(=O)CCCCF)cc1O* ; *OP(=O)(CCCCCCCF)O*]

In one or more embodiments, the second bank BN2 may have a multilayer structure including the second upper bank BN2b made of gold (Au), and the third bank BN3 may be connected to the second bank BN2 through an —S— bond. Gold (Au) may undergo a self-assembled reaction with alkylthiol, and the third bank BN3 may include the —S— bond on the surface of the second upper bank BN2b.

The display device 10 may include trace patterns TRP1 through TRP3, which are traces of a deposition process, on the bank structure BNS. The trace patterns TRP1 through TRP3 may include light emitting patterns ELP1 through ELP3, electrode patterns CEP1 through CEP3 and capping patterns CPP1 through CPP3, and may be disposed and provided on the third bank BN3 to surround the emission areas EA1 through EA3.

The trace patterns TRP1 through TRP3 may be traces formed as deposited materials are separated without being connected to the light emitting layers EL1 through EL3, the common electrodes CE1 through CE3, and the capping layers CAP1 through CAP3 in the emission areas EA1 through EA3 by the tips TIP of the bank structure BNS. When a light emitting material is entirely deposited, the light emitting layers EL1 through EL3 are formed within the openings, and the light emitting patterns ELP1 through ELP3 are formed on the bank structure BNS. The light emitting patterns ELP1 through ELP3 are separated from the light emitting layers EL1 through EL3 by the tips TIP of the bank structure BNS. The common electrodes CE1 through CE3/the electrode patterns CEP1 through CEP3 and the capping layers CAP1 through CAP3/the capping patterns CPP1 through CPP3 may also be separated by the tips TIP, and their traces may remain on the bank structure BNS. In other words, the trace patterns TRP1 through TRP3 may be the result of patterning performed around the emission areas EA1 through EA3 or the openings.

The display device 10 according to one or more embodiments may include a plurality of light emitting patterns ELP1 through ELP3 including the same material as the light emitting layers EL1 through EL3 and disposed on the bank structure BNS. Because the light emitting layers EL1 through EL3 are formed through a process of depositing materials on the entire surface of the display device 10, the materials that form the light emitting layers EL1 through EL3 may be deposited on the bank structure BNS in addition to the emission areas EA1 through EA3.

For example, in one or more embodiments, the display device 10 may include the light emitting patterns ELP1 through ELP3 on (e.g., disposed on) the bank structure BNS. The light emitting patterns ELP1 through ELP3 may include a first light emitting pattern ELP1, a second light emitting pattern ELP2, and a third light emitting pattern ELP3 on (e.g., disposed on) the third bank BN3 of the bank structure BNS.

The first light emitting pattern ELP1 may include the same material as the first light emitting layer EL1 of the first light emitting element ED1. The second light emitting pattern ELP2 may include the same material as the second light emitting layer EL2 of the second light emitting element ED2, and the third light emitting pattern ELP3 may include the same material as the third light emitting layer EL3 of the third light emitting element ED3. Each of the light emitting patterns ELP1 through ELP3 may be respectively formed in a process of forming the light emitting layer EL1, EL2, or EL3 including the same material as the light emitting pattern ELP1, ELP2, or ELP3. The light emitting patterns ELP1 through ELP3 may be disposed adjacent to the emission areas EA1 through EA3 in which the light emitting layers EL1 through EL3 are disposed, respectively.

The display device 10 according to one or more embodiments may include a plurality of electrode patterns CEP1 through CEP3 including the same material as the common electrodes CE1 through CE3 and on (e.g., disposed on) the bank structure BNS. A first electrode pattern CEP1, a second electrode pattern CEP2, and a third electrode pattern CEP3 may be directly disposed on the first light emitting pattern ELP1, the second light emitting pattern ELP2, and the third light emitting pattern ELP3, respectively. The arrangement relationship between the electrode patterns CEP1 through CEP3 and the light emitting patterns ELP1 through ELP3 may be the same as the arrangement relationship between the light emitting layers EL1 through EL3 and the common electrodes CE1 through CE3 of the light emitting elements ED1 through ED3.

In one or more embodiments, the display device 10 may include the capping patterns CPP1 through CPP3 on (e.g., disposed on) the bank structure BNS. A first capping patterns CPP1, a second capping pattern CPP2, and a third capping pattern CPP3 may be directly disposed on the first electrode pattern CEP1, the second electrode pattern CEP2, and the third electrode pattern CEP3, respectively. The arrangement relationship between the capping patterns CPP1 through CPP3 and the electrode patterns CEP1 through CEP3 may be the same as the arrangement relationship between the common electrodes CE1 through CE3 and the capping layers CAP1 through CAP3.

The thin-film encapsulation layer TFEL may be on (e.g., disposed on) the light emitting elements ED1 through ED3 and the bank structure BNS and may cover the light emitting elements ED1 through ED3 and the bank structure BNS. The thin-film encapsulation layer TFEL may include at least one inorganic layer to prevent or reduce oxygen and/or moisture from penetrating into the light emitting element layer EML. The thin-film encapsulation layer TFEL may include at least one organic layer to protect the light emitting element layer EML from foreign substances such as dust.

In one or more embodiments, the thin-film encapsulation layer TFEL may include a lower inorganic encapsulation layer TFE1, an organic encapsulation layer TFE2, and an upper inorganic encapsulation layer TFE3 stacked sequentially.

Each of the lower inorganic encapsulation layer TFE1 and the upper inorganic encapsulation layer TFE3 may include at least one inorganic insulating material. The inorganic insulating material may include or be at least one (e.g., one or more) selected from among silicon oxide, silicon nitride, and silicon oxynitride, and/or, for example, may be aluminum oxide, titanium oxide, tantalum oxide, hafnium oxide, zinc oxide, silicon oxide, silicon nitride, and/or silicon oxynitride.

The organic encapsulation layer TFE2 may include a polymer-based material. Non-limiting examples of the polymer-based material may include acrylic-based resins, epoxy-based resins, polyimide, and polyethylene. For example, in some embodiments, the organic encapsulation layer TFE2 may include an acrylic-based resin such as polymethyl methacrylate and/or polyacrylic acid. The organic encapsulation layer TFE2 may be formed by curing a monomer or applying a polymer.

The lower inorganic encapsulation layer TFE1 may be on (e.g., disposed on) the light emitting elements ED1 through ED3, the trace patterns TRP1 through TPR3, and the bank structure BNS. The lower inorganic encapsulation layer TFE1 may include the first inorganic layer TL1, a second inorganic layer TL2, and a third inorganic layer TL3 disposed to correspond to different emission areas EA1 through EA3, respectively. The first inorganic layer TL1, the second inorganic layer TL2, and the third inorganic layer TL3 may include an inorganic insulating material to cover the light emitting elements ED1 through ED3, respectively. The first inorganic layer TL1, the second inorganic layer TL2, and the third inorganic layer TL3 may prevent or reduce the light emitting elements ED1 through ED3 from being damaged by external air.

Because the lower inorganic encapsulation layer TFE1 (TL1 through TL3) can be formed through chemical vapor deposition (CVD), it may be formed along steps of layers on which it is deposited. For example, each of the first inorganic layer TL1, the second inorganic layer TL2, and the third inorganic layer TL3 may form a thin layer even under an undercut formed by a tip TIP of the bank structure BNS. The lower inorganic encapsulation layer TL1 through TL3 may be disposed on the light emitting elements ED1 through ED3, the electrode patterns CEP1 through CEP3, and the bank structure BNS. The first inorganic layer TL1 may be disposed along the first light emitting element ED1, the first capping layer CAP1, and the side surfaces of the first bank BN1 which are adjacent to the first common electrode CE1 to cover them. In some embodiments, the first inorganic layer TL1 may pass the side surfaces of the second bank BN2 and the third bank BN3 and cover the first light emitting pattern ELP1, the first electrode pattern CEP1, and the first capping pattern CPP1.

The first inorganic layer TL1 may not overlap a second opening and a third opening and may be disposed and provided only in a first opening and on the first light emitting element ED1 and the bank structure BNS around the first light emitting element ED1. The second inorganic layer TL2 may not overlap the first opening and the third opening and may be disposed and provided only in the second opening and on the second light emitting element ED2 and the bank structure BNS around the second light emitting element ED2. The third inorganic layer TL3 may not overlap the first opening and the second opening and may be disposed and provided only in the third opening and on the third light emitting element ED3 and the bank structure BNS around the third light emitting element ED3.

The first inorganic layer TL1 may be formed after the first common electrode CE1 is formed, the second inorganic layer TL2 may be formed after the second common electrode CE2 is formed, and the third inorganic layer TL3 may be formed after the third common electrode CE3 is formed. The first inorganic layer TL1, the second inorganic layer TL2, and the third inorganic layer TL3 may be spaced and/or apart from each other on the bank structure BNS. Accordingly, a portion of the third bank BN3 may not overlap the first through third inorganic layers TL1 through TL3, and a portion of an upper surface of the third bank BN3 may be exposed without being covered by the first through third inorganic layers TL1 through TL3 in a space between the first through third inorganic layers TL1 through TL3. The exposed upper surface of the third bank BN3 may directly contact the organic encapsulation layer TFE2 of the thin-film encapsulation layer TFEL.

The first inorganic layer TL1, the second inorganic layer TL2, and the third inorganic layer TL3 may have substantially the same or similar boundaries as the first through third trace patterns TRP1 through TRP3, respectively, and may have a larger area than the openings of the bank structure BNS or the emission areas EA1 through EA3. The trace patterns TRP1 through TRP3 may be made to have boundary lines located inside the lower inorganic encapsulation layer TL1 through TL3 by adjusting a process of removing/etching the electrode patterns CEP1 through CEP3 and the light emitting patterns ELP1 through ELP3 of the trace patterns TRP1 through TRP3. For example, the trace patterns TRP1 through TRP3 may have boundary lines closer to the emission areas EA1 through EA3 than the lower inorganic encapsulation layer TL1 through TL3.

The organic encapsulation layer TFE2 may be on (e.g., disposed on) the third bank BN3 and the lower inorganic encapsulation layer TL1 through TL3. A portion of the organic encapsulation layer TFE2 may contact the third bank BN3.

The upper inorganic encapsulation layer TFE3 may be on (e.g., disposed on) the organic encapsulation layer TFE2. The upper inorganic encapsulation layer TFE3 may include aluminum oxide, titanium oxide, tantalum oxide, hafnium oxide, zinc oxide, silicon oxide, silicon nitride, and/or silicon oxynitride.

The light blocking layer BM may be on (e.g., disposed on) the thin-film encapsulation layer TFEL. The light blocking layer BM may include a plurality of holes OPT1 through OPT3 overlapping the emission areas EA1 through EA3, respectively. For example, a first hole OPT1 may overlap the first emission area EA1. A second hole OPT2 may overlap the second emission area EA2, and a third hole OPT3 may overlap the third emission area EA3. The areas or sizes of the holes OPT1 through OPT3 may be larger than the areas or sizes of the emission areas EA1 through EA3, respectively. Because the holes OPT1 through OPT3 of the light blocking layer BM are formed to be larger than the emission areas EA1 through EA3, light emitted from the emission areas EA1 through EA3 can be seen by a user not only from the front but also from the side of the display device 10.

The light blocking layer BM may include a light absorbing material. For example, in one or more embodiments, the light blocking layer BM may include an inorganic black pigment and/or an organic black pigment. The inorganic black pigment may be carbon black, and the organic black pigment may include at least one of lactam black, perylene black, or aniline black. However, embodiments of the present disclosure are not limited thereto. The light blocking layer BM may prevent or reduce color mixing by preventing or reducing intrusion of visible light between the first through third emission areas EA1 through EA3, thereby improving a color gamut of the display device 10.

The display device 10 may include a plurality of color filters CF1 through CF3 on (e.g., disposed on) the emission areas EA1 through EA3. The color filters CF1 through CF3 may be disposed to correspond to the emission areas EA1 through EA3, respectively. For example, the color filters CF1 through CF3 may be disposed on the light blocking layer BM including the holes OPT1 through OPT3 corresponding to the emission areas EA1 through EA3. The holes OPT1 through OPT3 of the light blocking layer BM may be formed to overlap the emission areas EA1 through EA3 or the openings of the bank structure BNS and may form light output areas through which light emitted from the emission areas EA1 through EA3 is output. The color filters CF1 through CF3 may have a larger area than that of the holes OPT1 through OPT3 of the light blocking layer BM, respectively. The color filters CF1 through CF3 may completely cover the light output areas formed by the holes OPT1 through OPT3, respectively.

The color filters CF1 through CF3 may include a first color filter CF1, a second color filter CF2, and a third color filter CF3 disposed to correspond to different emission areas EA1 through EA3, respectively. Each of the color filters CF1 through CF3 may include a colorant such as a dye and/or a pigment that absorbs light in wavelength bands other than light in a specific wavelength band and may be disposed to correspond to the color of light emitted from one of the emission areas EA1 through EA3. For example, in some embodiments, the first color filter CF1 may be a red color filter that overlaps the first emission area EA1 and transmits only red first light. The second color filter CF2 may be a green color filter that overlaps the second emission area EA2 and transmits only green second light, and the third color filter CF3 may be a blue color filter that overlaps the third emission area EA3 and transmits only blue third light.

Each of the color filters CF1 through CF3 may be spaced and/or apart from other adjacent color filters CF1 through CF3 on the light blocking layer BM. The color filters CF1 through CF3 may respectively cover the holes OPT1 through OPT3 of the light blocking layer BM and may have a larger area than that of the holes OPT1 through OPT3. However, each of the color filters CF1 through CF3 may have an area large enough for it to be spaced and/or apart from other color filters CF1 through CF3 on the light blocking layer BM. However, embodiments of the present disclosure are not limited thereto. In some embodiments, each of the color filters CF1 through CF3 may also partially overlap adjacent color filters CF1 through CF3. In these embodiments, portions of different color filters CF1 through CF3 which do not overlap the emission areas EA1 through EA3 may overlap each other on the light blocking layer BM which will be described later. Because the color filters CF1 through CF3 overlap each other in the display device 10, the intensity of reflected light caused by external light may be reduced. Further, the color of reflected light caused by external light may be controlled or selected by adjusting the arrangement, shapes, and/or areas of the color filters CF1 through CF3 in plan view.

An overcoat layer OC may be disposed on the color filters CF1 through CF3 to planarize upper ends of the color filters CF1 through CF3. The overcoat layer OC may be a colorless light-transmitting layer that does not have a color in a visible light band. For example, the overcoat layer OC may include a colorless light-transmitting organic material such as acrylic-based resins.

A display device according to one or more embodiments includes a third bank on (e.g., disposed on) a second bank. Therefore, an etchant may be prevented or reduced from penetrating into light emitting elements during an etching process. Because damage to the light emitting elements due to the etchant or moisture is prevented or reduced, a difference in luminance between the light emitting elements may be reduced.

However, the effects and benefits of the present disclosure are not restricted to the one set forth herein. The above and other effects and benefits of the present disclosure will become more apparent to one of daily skill in the art to which the disclosure pertains by referencing the claims.

In the present disclosure, it will be understood that the terms “comprise(s),” “include(s),” or “have/has” specify the presence of stated features, integers, steps, operations, elements, and/or components, but do not preclude the presence or addition of one or more other features, integers, steps, operations, elements, components, and/or groups thereof.

As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure”.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

The light emitting element, the display device, the electronic apparatus, the electronic equipment, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

While the disclosure has been particularly illustrated and described with reference to embodiments thereof, it will be understood by those of ordinary skill in the art that one or more suitable changes in form and detail may be made therein without departing from the spirit and scope of the disclosure as defined by the appended claims and equivalents thereof. The embodiments should be considered in a descriptive sense only and not for purposes of limitation.

1 what is claimed is:

1. A display device comprising:
a first pixel electrode on a substrate;
a pixel defining layer on the substrate and exposing the first pixel electrode;
a first light emitting layer on the first pixel electrode;
a first common electrode on the first light emitting layer;
a first bank on the pixel defining layer;
a second bank on the first bank and comprising side surfaces protruding more than side surfaces of the first bank; and
a third bank on upper and lower surfaces of the second bank.

2. The display device of claim 1, wherein a thickness of the third bank is about 5 nanometer (nm) to about 100 nm.

3. The display device of claim 2, wherein the thickness of the third bank on the upper surface of the second bank and the thickness of the third bank on the lower surface of the second bank are different from each other.

4. The display device of claim 1, further comprising a first inorganic layer on the third bank and the first common electrode.

5. The display device of claim 1, wherein the third bank completely covers the second bank.

6. The display device of claim 1, wherein the third bank contacts at least a portion of the lower surface of the second bank.

7. The display device of claim 1, wherein the third bank comprises a hydrophobic material.

8. The display device of claim 7, wherein the third bank is a self-assembled monolayer.

9. The display device of claim 7, wherein the third bank comprises fluorine.

10. The display device of claim 9, wherein the third bank comprises an —O— or —S— bond on a surface of the second bank.

11. The display device of claim 10, wherein the second bank comprises a second lower bank on the first bank and a second upper bank on the second lower bank, the second upper bank comprising gold, and
wherein the third bank comprises an —S— bond on a surface of the second upper bank.

12. The display device of claim 4, further comprising a first capping layer between the first common electrode and the first inorganic layer.

13. The display device of claim 1, wherein an end and the other end of the first common electrode contact the first bank.

14. The display device of claim 4, further comprising:
a second pixel electrode on the substrate and spaced from the first pixel electrode;
a second light emitting layer on the second pixel electrode;
a second common electrode on the second light emitting layer and spaced from the first common electrode; and
a second inorganic layer on the second common electrode and the second bank and spaced from the first inorganic layer.

15. The display device of claim 4, further comprising:
a first light emitting pattern between the third bank and the first inorganic layer and comprising the same material as the first light emitting layer; and
a first electrode pattern between the first light emitting pattern and the first inorganic layer and comprising the same material as the first common electrode.

16. A display device comprising:
a first pixel electrode on a substrate;
a pixel defining layer on the substrate and exposing the first pixel electrode;
a first light emitting layer on the first pixel electrode;
a first common electrode on the first light emitting layer;
a first bank on the pixel defining layer;
a second bank on the first bank and comprising side surfaces protruding more than side surfaces of the first bank; and
a third bank on the second bank and comprising fluorine.

17. The display device of claim 16, wherein the third bank is on upper and side surfaces of the second bank.

18. The display device of claim 16, wherein the third bank comprises a hydrophobic material.

19. The display device of claim 18, wherein the third bank comprises an —O— or —S— bond on a surface of the second bank.

20. The display device of claim 18, wherein the third bank forms an —O—P— or —O—Si— bond with a surface of the second bank.
